(19) United States
(12) Patent Application Publication
(10) Pub. No.: US 2012/0112742 A1
(43) Pub. Date: May 10, 2012

(54) SPEED SENSOR

(76) Inventor: Ulrich Schrader, Wollstadt (DE)

(21) Appl. No.: 13/384,638

(22) PCT Filed: Jul. 1, 2010
(86) PCT No.: PCT/EP2010/059355

§ 371 Date: Jan. 18, 2012

(30) Foreign Application Priority Data
Jul. 28, 2009 (DE) 10 2009 035 065.9
Dec. 10, 2009 (DE) 10 2009 054 521.2

(51) Int. Cl. G01R 33/02

(52) U.S. Cl. 324/252

(57) ABSTRACT

A speed sensor having a sensor housing for accommodating a magnetic field sensor element, an adapter for holding the sensor housing and a magnetic encoder. The invention provides for the speed sensor to have a device for length adaptation or air gap adjustment, and for the device to have a clamping mechanism for holding the sensor housing.

### CROSS REFERENCE TO RELATED APPLICATIONS

This application is the U.S. National Phase Application of PCT/EP2010/059355, filed Jul. 1, 2010, which claims priority to German Patent Application No. 10 2009 035 065.9, filed Jul. 28, 2009 and German Patent Application No. 10 2009 054 521.2, filed Dec. 10, 2009, the contents of such applications being incorporated by reference herein.

### FIELD OF THE INVENTION

The invention relates to a speed sensor, in particular a wheel speed sensor having a sensor housing for accommodating a magnetic field sensor element, an adapter for holding the sensor housing and a magnetic encoder, and to the use of the speed sensor in motor vehicles.

### BACKGROUND OF THE INVENTION

Various configurations of such speed sensors are already known. The air gap or the reading range of so-called active sensors as well is dependent on the pitch of the corresponding gearwheel or magnetic encoder. In installation situations in which a large number of pole pairs or teeth or a sensor wheel of small diameter, paired with large assembly tolerances, occurs, the function cannot be ensured using a sensor with fixed dimensions.

Known adjustable wheel speed sensors are fixed to a displaceable fastening bushing by means of a small clamping screw with an external hexagon. However, only length adaptations of the order of magnitude of 10 mm can be achieved thereby.

In another known length adaptation of a wheel speed sensor, the wheel sensor is pushed, together with a resilient sleeve, into a receiving hole. Since the sensor remains displaceable in this arrangement, there is the possibility, during driving operation, of the sensor being pushed so far out of the hole again that signal interference or signal losses can occur as a result of the changing air gap.

### SUMMARY OF THE INVENTION

Aspects of the invention relate to providing a speed sensor which is fixed such that it is adjustable in the longitudinal direction and is nevertheless secure in order to avoid signal interference on the basis of imprecise geometry.

This is achieved, according to aspects of the invention, by the features of a speed sensor having a sensor housing for accommodating a magnetic field sensor element, an adapter for holding the sensor housing and a magnetic encoder, wherein the speed sensor has a device for length adaptation or air gap adjustment, and in that the device has a clamping mechanism for holding the sensor housing.

The solution according to aspects of the invention surprisingly and simply provides a speed sensor with which the sensor housing is fixed such that it is adjustable in a simple and robust manner in the longitudinal direction and is nevertheless secure in order to avoid signal interference on account of undesirable changes in the distance between the sensor element and the encoder. The secure adjustment of the length of the wheel speed sensor also makes it possible to implement different installation situations with the sensor without having to produce a new sensor head for this purpose in each case, which may also be of interest, in particular, for small quantities.

In expedient embodiments of the speed sensor according to aspects of the invention, at least one of the following aspects can be advantageously expediently used with respect to the length adaptation and air gap adjustability:
A simple, that is to say without a fastening flange, universally usable housing for the active sensor element or the active speed sensor. Either magnetic encoders or steel gearwheels can be scanned by selecting only the corresponding sensor element.
Simple, robust elements for fixing the sensor housing in the longitudinal direction, illustrated or implemented, by way of example, by a clamping cone and a hollow screw as well as an associated adapter, which can be installed in previous standard sensor receiving holes.

The speed sensor is preferably in the form of a wheel speed sensor and is accordingly used as such.

The speed sensor preferably comprises at least one magnetic field sensor element and a magnetic encoder which comprises, in particular, at least one permanent-magnetic encoder track or an encoder track made of a magnetizable material, very particularly preferably in the form of a perforated disk or ring with stamped portions or a gearwheel.

The speed sensor preferably comprises a fastening device which is designed in such a manner that it can be used to adjust the air gap between the sensor element and the encoder.

The speed sensor is preferably in the form of an active sensor which requires electrical energy in order to operate at least its one magnetic field sensor element.

It is preferred for the speed sensor to have at least one magnetic field element, in particular a magnetoresistive sensor element or a Hall sensor element, an electronic signal processing circuit and, in particular, a plastic housing. This plastic housing is very particularly preferably substantially cylindrical.

It is expedient for the fastening device to comprise an adapter unit, a clamping ring and a pressure screw. In this case, the adapter unit is designed, in particular, in such a manner that it can accommodate the housing of the speed sensor in a recess in a manner safeguarded against rotation, and the recess of the adapter unit is designed in such a manner that it is suitable for receiving the clamping ring when arranged concentrically around the speed sensor housing, the adapter unit having a hole for fastening the entire speed sensor by means of a screw, for example.

A conical hole which forms a mating surface to the clamping ring is preferably provided in the central part of the adapter. The adapter expediently also comprises a threaded hole into which the pressure screw is screwed, which pressure screw axially loads the clamping ring and firmly braces the latter onto the sensor housing via the cone surfaces. On its outer surface, the clamping ring advantageously likewise has a cone corresponding to the cone hole in the adapter. The inner surface is designed in a manner corresponding to the sensor housing, with the result that a large clamping surface is ensured with an axial tensile stress.

In another embodiment, instead of the clamping ring, the clamping mechanism has an elastic shaping element which fixes the sensor housing by tightening the pressure screw using the transverse deformation. However, this fixing would then be less rigid, which may result in vibrations but would also result in a certain degree of flexibility when starting up the encoder on the sensor housing.

The speed sensor or wheel speed sensor or wheel sensor is thus designed, by way of example, in such a manner that the length of the air gap with respect to the magnetic encoder is adjustable in order to make it possible to compensate for the assembly tolerances in the vehicle: the air gap or the reading range, in particular of so-called active sensors, is dependent on the pitch of the corresponding gearwheel or magnetic encoder. In installation situations in which a large number of pole pairs or teeth or a sensor wheel of small diameter, paired with large assembly tolerances, occurs, the function cannot necessarily be ensured using a sensor with fixed dimensions.

Adjusting the length of the air gap or the positioning of the wheel speed sensor also makes it possible, for example, to handle different installation situations with a sensor without having to produce a new sensor head for this purpose, which may be of interest, in particular, for very small quantities. Previous adjustable wheel sensors were fixed, for example, to a displaceable fastening bushing by means of a small clamping screw, of the order of magnitude of an SW5 external hexagon. Only a length adaptation of the order of magnitude of 10 mm could also be achieved thereby.

Aspects of the invention also relate to the use of the speed sensor in motor vehicles, in particular in trucks.

### BRIEF DESCRIPTION OF THE DRAWINGS

The invention is best understood from the following detailed description when read in connection with the accompanying drawing. Included in the drawing is the following figure:

FIGS. 1 to 8 schematically illustrate various exemplary embodiments of speed sensor arrangements or speed sensors:

FIG. 1 shows a speed sensor housing with a fastening device,

FIG. 2 shows the speed sensor housing with the fastening device in the dismantled state,

FIG. 3 shows the speed sensor housing with a clamping ring and a pressure nut in the preassembled state,

FIG. 4 shows the front end of a speed sensor housing,

FIG. 5 shows a longitudinal section through a speed sensor housing with a fastening device,

FIG. 6 shows a front view of an adapter,

FIG. 7 shows a speed sensor in the installed state with axial scanning,

FIG. 8 shows a speed sensor in the installed state with radial scanning.

### DETAILED DESCRIPTION OF THE PREFERRED EMBODIMENTS

FIG. 1 shows a speed sensor housing 2 having a fastening device 4 in order to fasten the speed sensor housing to a vehicle, for example. For this purpose, provision is made of an adapter 6 which consists of a cylindrical main part 8, at one end of which a laterally protruding fastening flange 10 is provided. The fastening flange has a hole 12 through which a fastening screw 14 is inserted, which screw can be used to fasten the adapter to the vehicle, for example an axle part.

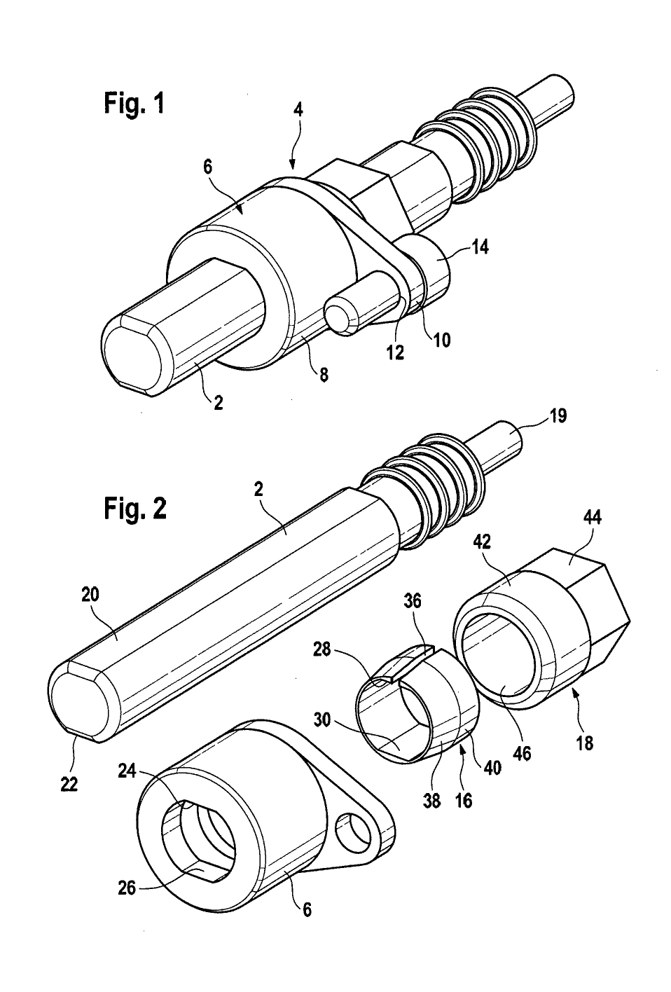

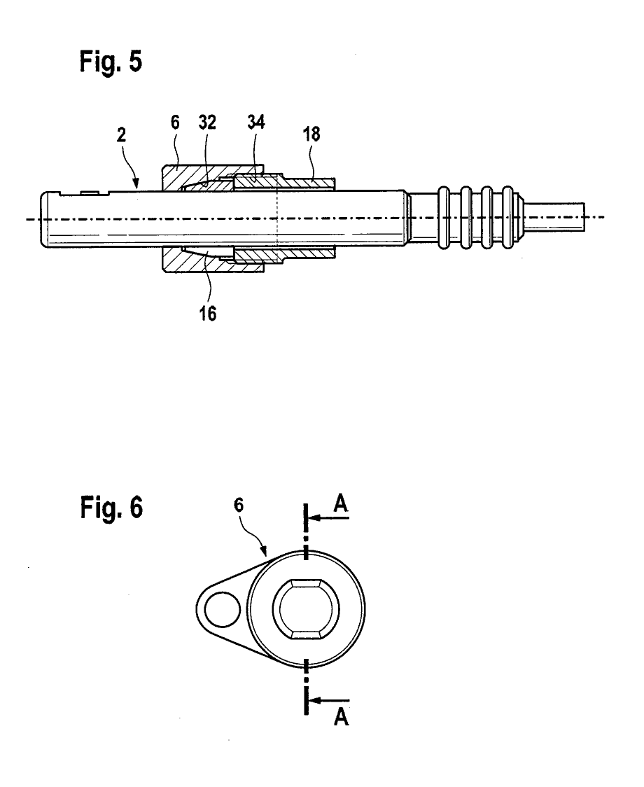

FIG. 2 illustrates individual parts of the arrangement in the dismantled state, namely the sensor housing 2, the adapter 6, a clamping ring 16 and a pressure screw 18. The sensor housing 2 is in the form of a rod and has, in its interior, a sensor element (not illustrated here) which is connected to a device for evaluating the sensor signals via a cable 19. On its outside, the sensor housing is provided with two flattened portions 20, 22 which form an antirotation safeguard with corresponding surfaces 24, 26 and 28, 30 in the adapter and in the clamping ring 16, respectively. The inside of the adapter 6 is provided with a cone 32 (see FIG. 5) and an internal thread 34. The clamping ring 16 has a longitudinal slot 36 as well as a cone 38 and a cylindrical part 40. At one end, the pressure screw 18 is provided with an external thread 42 and has an external hexagon 44 on the other side. The thread fit is expediently selected to be clamping in order to prevent independent release of the pressure screw 18. On the inside, the pressure screw 18 has a through-hole 46 for the passage of the sensor housing 2. The dimension of the hole is selected in such a manner that the sensor housing is additionally supported.

FIG. 3 shows the sensor housing 2, the clamping ring 16 and the pressure screw 18 in a preassembled state, the clamping ring 16 being pushed over the sensor housing 2 and the pressure screw 18 being pushed over the clamping ring 16.

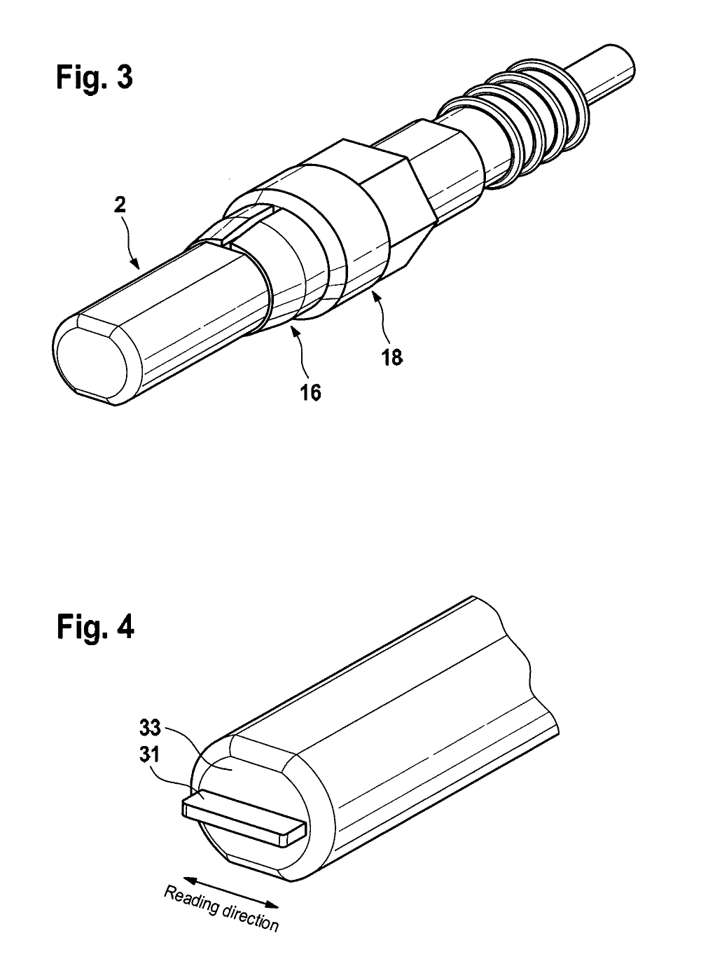

This sensor housing partially illustrated in FIG. 4 is designed in such a manner that a narrow rib 31 (of 0.5 mm-0.75 mm, for example) is integrated on the reading surface 33 of the sensor, thus making it possible to predefine a particular air gap with respect to the encoder, preferably for steel gearwheels. In the case of dynamic reductions in the air gap during driving operation, the rib 19 is accordingly ground by the gearwheel.

FIG. 5 illustrates a longitudinal section through the sensor housing 2 with the adapter 6, the clamping ring 16 and the pressure screw 18. The external thread 42 of the pressure screw 18 is screwed into the internal thread 34 of the adapter 6 and the end face of the pressure screw acts against the facing end face of the clamping ring, as a result of which its cone is pressed against the cone of the adapter. The clamping ring 16 and the sensor housing 2 are jammed against one another on account of the resultant forces. Since, as can be seen in FIG. 6 in particular, the sensor housing and the adapter are connected to one another in a rotationally fixed manner by means of the flattened portions 20, 22 and the surfaces 24, 26, an adjustable connection which is, however, rotationally fixed in the operating state and is secured against axial displacement is created.

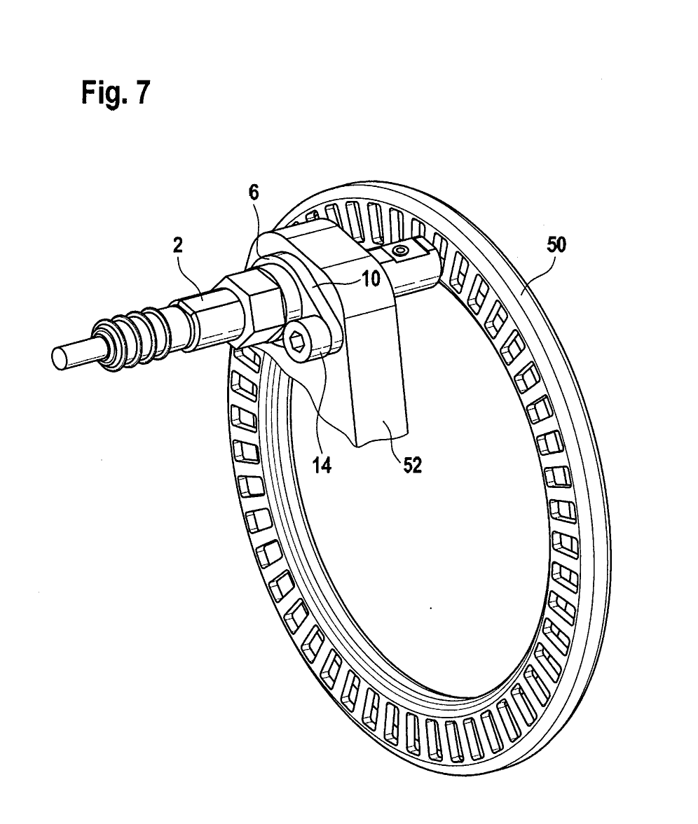

FIG. 7 shows a speed sensor with a housing 2, an adapter 6 and a pressure screw 18 in the installed state with axial scanning. In this case, the magnetic encoder 50 is in the form of a magnetizable punched ring which modulates the magnetic field produced by a permanent magnet (not illustrated) integrated in the speed sensor. In the case of this sensor, the speed sensor housing 2 is guided through a hole in a vehicle part 52 and is fastened to the vehicle by means of the fastening flange 10 provided on the adapter 6 and a fastening screw 14 in order to provide a secure hold. Instead of the fastening by means of the screw, other types of fastening also come, such as shrink-fit, press-fit or adhesively bonded connections. As previously described, the passage for the sensor housing in the adapter is flattened on two sides and thus ensures an antirotation safeguard. The front end of the speed sensor housing is opposite a magnetic encoder which is in the form of here. An air gap is situated between the end of the speed sensor housing and the encoder. The quality of the sensor signals depends on the accurate adjustment and retention of this air gap.

In this case, the sensor housing can be installed, for example, in conventional standard receiving holes with a nominal diameter of 16 or 18, for example.

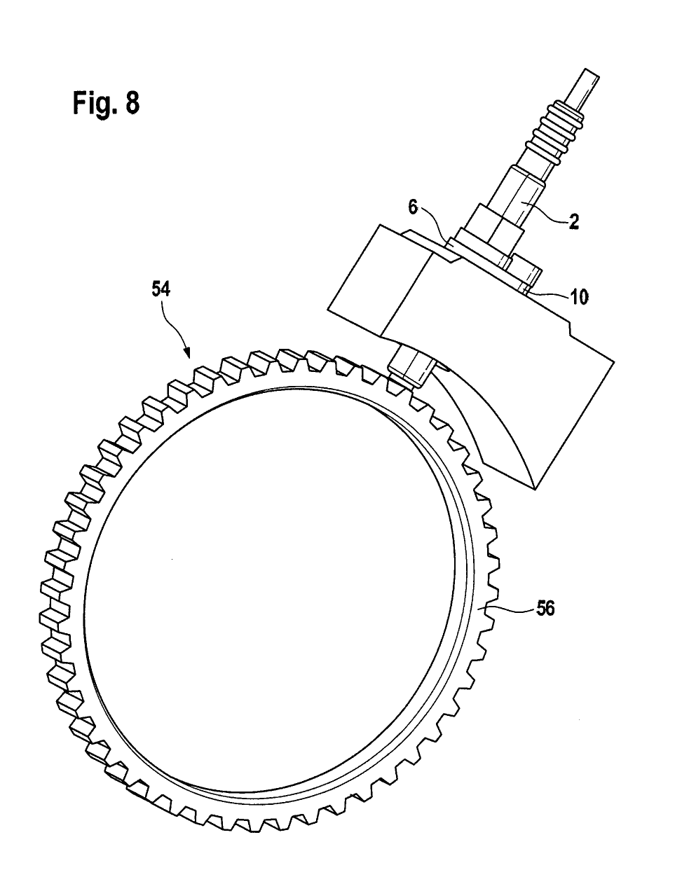

In the embodiment illustrated in FIG. 8, the sensor housing 2 is illustrated in the installed state, an encoder wheel 54 with a radial ring gear being radially scanned; like in the embodiment according to FIG. 7, the sensor housing is screwed to a vehicle part via the adapter.

The sensor can be installed in the vehicle, in particular the vehicle axle, as follows. The sensor is preassembled with the adapter, the clamping ring and the pressure screw and is delivered to the customer with the length preset, said customer inserting the sensor into the axle part and screwing it or fastening it to the axle part in another manner, as described above. Shrink-fit or press-fit connections are less suitable, however, with this assembly sequence. With another assembly sequence, the adapter with the clamping ring and the pressure screw is fitted in the axle part and the sensor is subsequently pushed in, if appropriate onto a stop, and is fixed using the pressure screw. A third assembly sequence provides for only the adapter to be first of all introduced into the axle part. The sensor with the pressure screw, which has been pushed on, and the clamping ring is then subsequently fitted into the adapter. This sequence is appropriate, in particular, if the adapter is intended to have a press fit or a shrink fit or is intended to be adhesively bonded.

### REFERENCE SYMBOLS

2 Speed sensor housing
4 Fastening device
6 Adapter
8 Main part
10 Fastening flange
12 Hole
14 Fastening screw
16 Clamping ring
18 Pressure screw
19 Cable
20, 22 Flattened portion
24, 26 Surface
28, 30 Surface
31 Rib
32 Cone
33 Reading surface
34 Internal thread
36 Longitudinal slot
38 Cone
40 Cylindrical part
42 External thread
44 External hexagon
46 Through-hole
50 Encoder
52 Vehicle part
54 Encoder wheel
56 Radial ring gear

1.-10. (canceled)

11. A speed sensor for use with a magnetic encoder, the speed sensor comprising:
a sensor housing for accommodating a magnetic field sensor element;
an adapter for holding the sensor housing; and
a device for length adaptation or air gap adjustment, the device having a clamping mechanism for holding the sensor housing.

12. The speed sensor as claimed in claim 11, wherein the clamping mechanism has a clamping ring which encompasses the sensor housing.

13. The speed sensor as claimed in claim 12, wherein the clamping ring has a cone which interacts with a mating cone in the adapter.

14. The speed sensor as claimed in claim 12, wherein the clamping ring is held in an axially braceable manner on the adapter, in particular by means of a pressure screw.

15. The speed sensor as claimed in claim 14, wherein a pressure screw for holding the clamping ring in an axially braceable manner can be screwed to the adapter.

16. The speed sensor as claimed in claim 11, wherein the sensor housing has an antirotation safeguard.

17. The speed sensor as claimed in claim 16, wherein, for the antirotation safeguard, the sensor housing has at least one flattened portion which interacts with a corresponding mating surface.

18. The speed sensor as claimed in claim 11, wherein the sensor housing has a rib facing the encoder.

19. The speed sensor as claimed in claim 11, wherein the sensor is an active sensor.

20. The speed sensor as claimed in in claim 11, wherein the magnetic field sensor element operates using the magnetoresistive or Hall principle.
